(19) United States
(12) Patent Application Publication
(10) Pub. No.: US 2014/0139985 A1
(43) Pub. Date: May 22, 2014

(54) ENVIRONMENTAL SENSITIVE ELECTRONIC DEVICE PACKAGE

(71) Applicant: Industrial Technology Research Institute, Hsinchu (TW)

(72) Inventor: Ping-I Shih, Chiayi County (TW)

(73) Assignee: Industrial Technology Research Institute, Hsinchu (TW)

(21) Appl. No.: 14/077,217

(22) Filed: Nov. 12, 2013

Related U.S. Application Data
(60) Provisional application No. 61/725,031, filed on Nov. 12, 2012.

(30) Foreign Application Priority Data
Nov. 5, 2013 (TW) 102140175

(51) Int. Cl. H05K 7/06

(52) U.S. Cl. CPC H05K 7/06
USPC 361/679.01

(57) ABSTRACT

An environmental sensitive electronic device package includes a first substrate, a second substrate, an environmental sensitive electronic device, at least one side wall barrier structure, and a filler layer. The second substrate is disposed above the first substrate. The environmental sensitive electronic device is disposed on the first substrate and located between the first substrate and the second substrate. The side wall barrier structure is located between the first substrate and the second substrate and surrounds the environmental sensitive electronic device. The side wall barrier structure extends along a path, and the height of the side wall barrier structure varies along the path. The filler layer is located between the first substrate and the second substrate and covers the side wall barrier structure and the environmental sensitive electronic device.

### CROSS-REFERENCE TO RELATED APPLICATION

This application claims the priority benefits of U.S. provisional application Ser. No. 61/725,031, filed on Nov. 12, 2012 and Taiwan application serial no. 102140175, filed on Nov. 5, 2013. The entirety of each of the above-mentioned patent applications is hereby incorporated by reference herein and made a part of this specification.

### TECHNICAL FIELD

The technical field relates to an environmental sensitive electronic device package.

### BACKGROUND

With the progress of industrial technology, rigid and inflexible interfaces of electronic devices have been gradually replaced by flexible interfaces; in response thereto, the substrates of the electronic devices tend to be made of different materials. The flexible substrates have been applied in replacement of the rigid glass substrates. The flexible electronic devices have suffered from poor resistance to moisture and oxygen; in order to effectively extend the lifetime of the flexible electronic devices, the flexible electronic devices may be packaged so as to block moisture or oxygen.

### SUMMARY

According to an exemplary embodiment of the disclosure, an environmental sensitive electronic device package that includes a first substrate, a second substrate, an environmental sensitive electronic device, at least one side wall barrier structure, and a filler layer is provided. The second substrate is disposed above the first substrate. The environmental sensitive electronic device is disposed on the first substrate and located between the first substrate and the second substrate. The side wall barrier structure is located between the first substrate and the second substrate and surrounds the environmental sensitive electronic device. The side wall barrier structure extends along a path, and a height of the side wall barrier structure varies along the path. The filler layer is located between the first substrate and the second substrate and covers the side wall barrier structure and the environmental sensitive electronic device.

According to an exemplary embodiment of the disclosure, an environmental sensitive electronic device package that includes a first substrate, a second substrate, an environmental sensitive electronic device, at least one first side wall barrier structure, at least one second side wall barrier structure, and a filler layer is provided. The second substrate is disposed above the first substrate. The environmental sensitive electronic device is disposed on the first substrate and located between the first substrate and the second substrate. The first side wall barrier structure is disposed on the first substrate and located between the first substrate and the second substrate. The first side wall barrier structure surrounds the environmental sensitive electronic device. The first side wall barrier structure extends along a path, and a height of the first side wall barrier structure remains constant. The second side wall barrier structure is disposed on the second substrate and located between the first substrate and the second substrate. The second side wall barrier structure surrounds the environmental sensitive electronic device. The second side wall barrier structure extends along another path, and a height of the second side wall barrier structure remains constant. The filler layer is located between the first substrate and the second substrate and covers the first side wall barrier structure, the second side wall barrier structure, and the environmental sensitive electronic device.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a schematic cross-sectional view illustrating an environmental sensitive electronic device package according to an exemplary embodiment of the disclosure.

FIG. 1B is a top view illustrating the environmental sensitive electronic device package depicted in FIG. 1A.

FIG. 2A to FIG. 2G are schematic partial cross-sectional diagrams illustrating the environmental sensitive electronic device package depicted in FIG. 1A along a sectional line I-I′ according to several exemplary embodiments of the disclosure.

FIG. 3A and FIG. 3B are schematic cross-sectional diagrams respectively illustrating an environmental sensitive electronic device package according to another exemplary embodiment of the disclosure.

FIG. 4A to FIG. 4E are schematic cross-sectional diagrams illustrating an environmental sensitive electronic device package according to another exemplary embodiment of the disclosure.

FIG. 5A to FIG. 5D are schematic cross-sectional diagrams illustrating an environmental sensitive electronic device package according to another exemplary embodiment of the disclosure.

FIG. 6A is a schematic cross-sectional diagram illustrating an environmental sensitive electronic device package according to another exemplary embodiment of the disclosure.

FIG. 6B is a top view illustrating the environmental sensitive electronic device package depicted in FIG. 6A.

FIG. 6C is a schematic partial cross-sectional diagram illustrating the environmental sensitive electronic device package depicted in FIG. 6A along a sectional line J-J′.

FIG. 6D to FIG. 6G are schematic cross-sectional diagrams illustrating an environmental sensitive electronic device package according to yet another exemplary embodiment of the disclosure.

### DETAILED DESCRIPTION OF DISCLOSED EMBODIMENTS

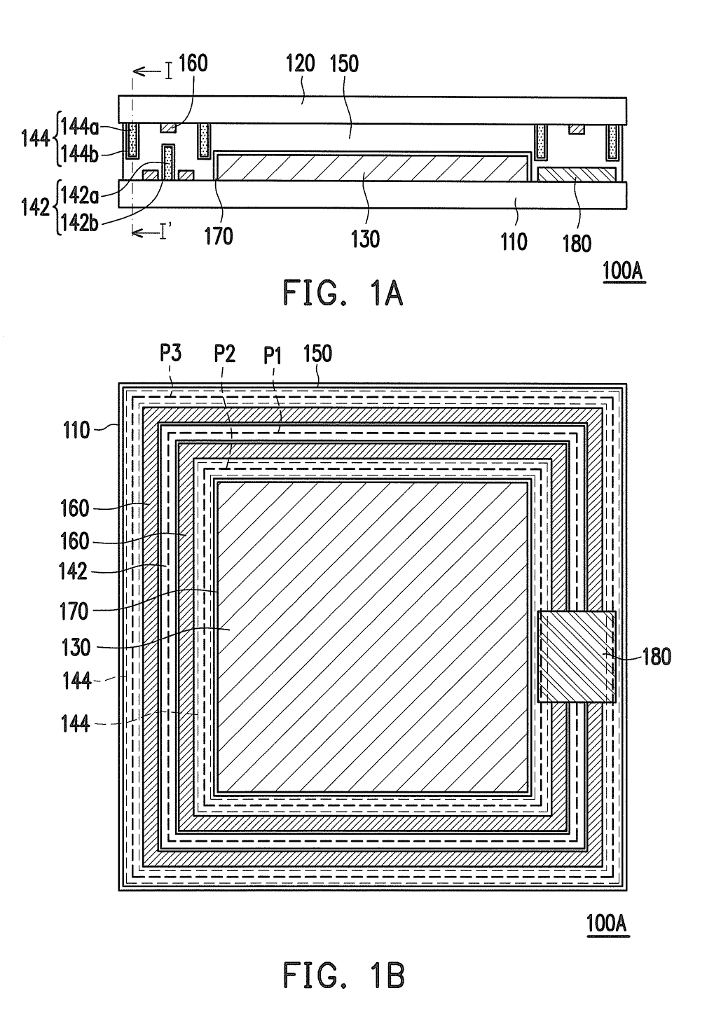

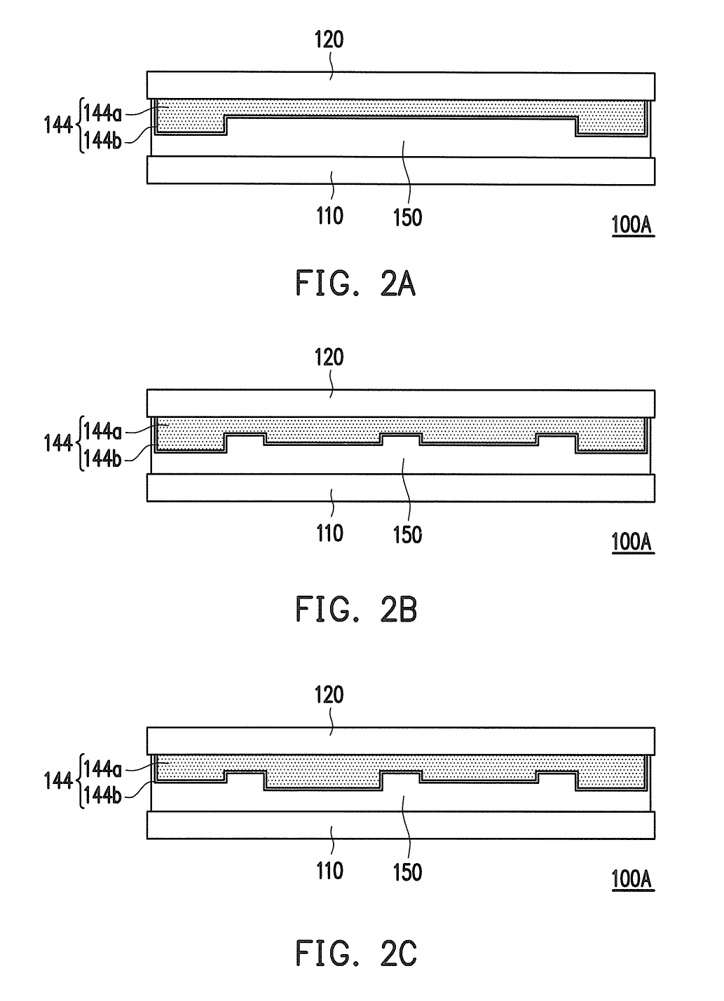

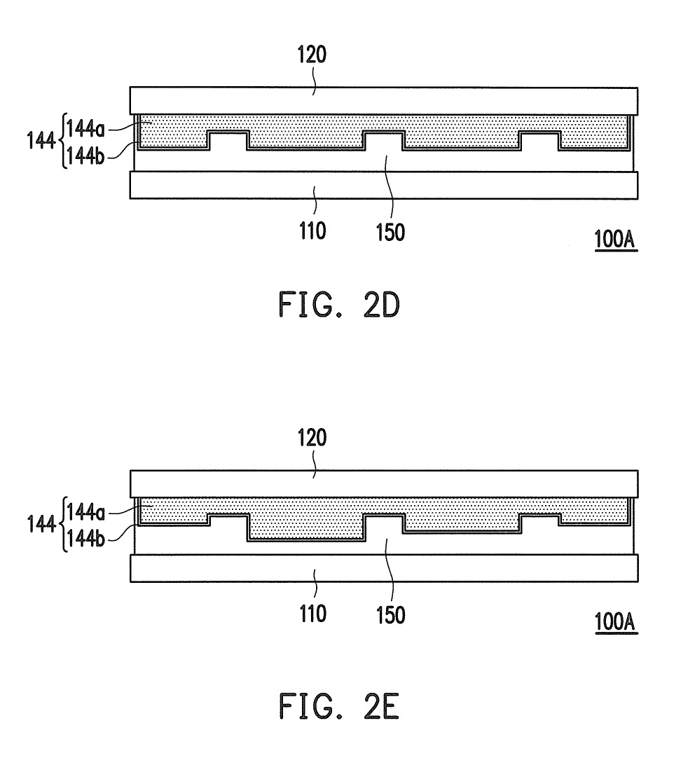

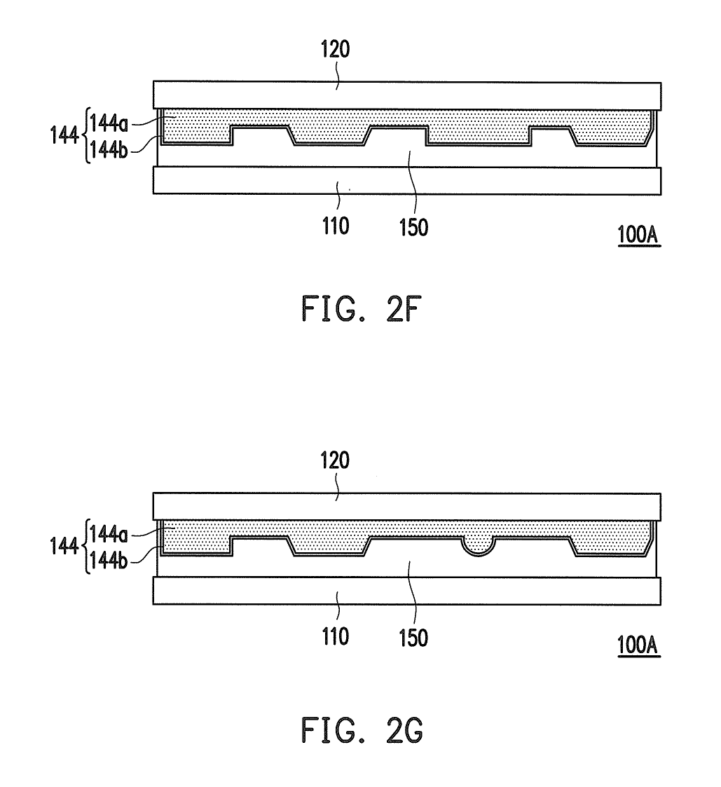

FIG. 1A is a schematic cross-sectional view illustrating an environmental sensitive electronic device package according to an exemplary embodiment of the disclosure. FIG. 1B is a top view illustrating the environmental sensitive electronic device package depicted in FIG. 1A. FIG. 2A to FIG. 2G are schematic partial cross-sectional diagrams illustrating the environmental sensitive electronic device package depicted in FIG. 1A along a sectional line I-I′ according to several exemplary embodiments of the disclosure. With reference to FIG. 1A and FIG. 1B, in the present exemplary embodiment of the disclosure, the environmental sensitive electronic device package 100A includes a first substrate 110, a second substrate 120, an environmental sensitive electronic device 130, a first side wall barrier structure 142, a second side wall barrier structure 144, and a filler layer 150. The second substrate 120 is disposed above the first substrate 110. The environmental sensitive electronic device 130 is disposed on the first substrate 110 and located between the first substrate 110 and the second substrate 120. The first side wall barrier structure 142 and the second side wall barrier structure 144 are located between the first substrate 110 and the second substrate 120 and respectively surround the environmental sensitive electronic device 130.

The first side wall barrier structure 142 extends along a path P1, and the second side wall barrier structure 144 extends respectively along a path P2 and a path P3. A height of the first side wall barrier structure 142 varies along the path P1, and a height of the second side wall barrier structure 144 varies along the paths P2 and P3, respectively, as shown in FIG. 2A to FIG. 2G. The filler layer 150 is located between the first substrate 110 and the second substrate 120 and covers the first side wall barrier structure 142, the second side wall barrier structure 144, and the environmental sensitive electronic device 130.

In the present exemplary embodiment, the first substrate 110 and the second substrate 120 are flexible substrates, for instance, and a material of the flexible substrates may be glass, polyethylene terephthalate (PET), polyethylene naphthalate (PEN), polyethersulfone (PES), polymethyl methacrylate (PMMA), polycarbonate (PC), polyimide (PI), or metal foil. The environmental sensitive electronic device package 100A may further include a functional film (not shown) exemplarily located on the first substrate 110 or on the second substrate 120. In general, the functional film may be a touch panel, and the touch panel may refer to a surface capacitive touch panel, a digital matrix touch panel (e.g., a projection capacitive touch panel), or an analog matrix touch panel, for instance. Certainly, the functional film may be a color filter or an electrophoretic display (EPD). In brief, the environmental sensitive electronic device package described in an exemplary embodiment of the disclosure is capable of performing the touch function.

The environmental sensitive electronic device 130 is, for instance, an active environmental sensitive electronic display device or a passive environmental sensitive electronic display device. The active environmental sensitive electronic display device is, for instance, an active matrix organic light emitting diode (AM-OLED), an active matrix electrophoretic display (AM-EPD) commonly known as electronic paper, an active matrix liquid crystal display (AM-LCD), or an active matrix blue phase liquid crystal display (AMBPLCD). The passive environmental sensitive electronic display device is, for instance, a passive matrix OLED (PM-OLED) or a super twisted nematic liquid crystal display (STN-LCD). According to the present exemplary embodiment, the environmental sensitive electronic device 130 is covered by a passivation layer 170. The passivation layer 170 may be an optical film or any other transparent polymer material film, which should not be construed as a limitation in the disclosure. The passivation layer 170 is capable of enhancing the brightness of the environmental sensitive electronic device 130 and blocking moisture and oxygen. Thereby, the lifetime of the environmental sensitive electronic device 130 may be extended.

As shown in FIG. 1A, in the present exemplary embodiment, the first side wall barrier structure 142 and the second side wall barrier structure 144 may be respectively located on the first substrate 110 and the second substrate 120. Here, the first side wall barrier structure 142 and the second side wall barrier structure 144 are alternately arranged between the first substrate 110 and the second substrate 120.

The first side wall barrier structure 142 extends toward the second substrate 120, and the second side wall barrier structure 144 extends toward the first substrate 110. Here, a shape of a cross-section of the first side wall barrier structure 142 perpendicular to the first substrate 110 is a rectangular shape, for instance. In another aspect, a cross-section of the second side wall barrier structure 144 perpendicular to the second substrate 120 is shaped as a rectangle as well, for instance. In other exemplary embodiments of the disclosure, the shape of the cross-section may be a trapezoidal shape, any other polygonal shape, a bullet shape, a circular shape, or an elliptic shape, which should not be construed as a limitation in the disclosure.

According to the present exemplary embodiment, the first side wall barrier structure 142 may further include a first barrier layer 142a and a first cover layer 142b. The first barrier layer 142a is located on the first substrate 110 and covered by the first cover layer 142b. A material of the first barrier layer 142a may include an inorganic material or a mixture of inorganic and organic materials, and the first barrier layer 142a is formed on the first substrate 110 through etching, printing, photolithography, or the like, for instance. From another perspective, a material of the first cover layer 142b includes an inorganic material or a metal material. Here, the inorganic material is, for instance, silicon oxide, silicon nitride, silicon oxynitride, or aluminum oxide; the metal material is, for instance, molybdenum, titanium, aluminum, chromium, molybdenum/aluminum/molybdenum, or titanium/aluminum/titanium. The first cover layer 142b is formed on the first barrier layer 142a through wet coating, film evaporation, film sputtering, or the like, for instance. The first side wall barrier structure 142 and the first substrate 110 may be made of the same material or different materials, which should not be construed as a limitation in the disclosure.

According to the present exemplary embodiment, the second side wall barrier structure 144 may include a second barrier layer 144a and a second cover layer 144b. The second barrier layer 144a is located on the second substrate 120 and covered by the second cover layer 144b. A material of the second barrier layer 144a may include an inorganic material or a mixture of inorganic and organic materials, and the second barrier layer 144a is formed on the second substrate 120 through etching, printing, photolithography, or the like, for instance. From another perspective, a material of the second cover layer 144b includes an inorganic material or a metal material. Here, the inorganic material is, for instance, silicon oxide, silicon nitride, silicon oxynitride, or aluminum oxide; the metal material is, for instance, molybdenum, titanium, aluminum, chromium, molybdenum/aluminum/molybdenum, or titanium/aluminum/titanium. The second cover layer 144b is formed on the second barrier layer 144a through wet coating, film evaporation, film sputtering, or the like, for instance. The second side wall barrier structure 144 and the second substrate 120 may be made of the same material or different materials, which should not be construed as a limitation in the disclosure.

It should be mentioned that the side wall barrier structures having the barrier layers and the cover layers, as provided above, are exemplary and should not be construed as limitations in the disclosure; in other exemplary embodiments that are not shown in the drawings, the first side wall barrier structure 142 may be a gas barrier structure merely equipped with the first barrier layer 142a, and the second side wall barrier structure 144 may be another gas barrier structure merely equipped with the second barrier layer 144a. The filler layer 150 that covers the first side wall barrier structure 142 and the second side wall barrier structure 144 is formed by curing an adhesive with use of ultraviolet light or heat, for instance. The adhesive is, for instance, made of acrylic resin or epoxy resin. In the present exemplary embodiment, the filler layer 150 is a pressure-sensitive-type adhesive or a fill-type adhesive, for instance.

With reference to FIG. 1B, in the present exemplary embodiment, both the first side wall barrier structure 142 and the second side wall barrier structure 144 may have continuous and closed annular structures. In other exemplary embodiments of the disclosure, the first side wall barrier structure 142 and the second side wall barrier structure 144 may be closed or non-closed structures. For instance, the orthogonal projection of the first side wall barrier structure 142 on the first substrate 110 and the orthogonal projection of the second side wall barrier structure 144 on the second substrate 120 may be a U-shaped pattern, an L-shaped pattern, a dotted pattern, or any other pattern that may partially surround the environmental sensitive electronic device. The disclosure is not limited thereto.

That is, each of the first side wall barrier structure 142 and the second side wall barrier structure 144 may include a plurality of separated segments respectively surrounding the environmental sensitive electronic device along said extension path, and a height of at least one of the separated segments varies along said extension path.

As shown in FIG. 1A and FIG. 1B, in the present exemplary embodiment, a moisture absorption layer 160 may be disposed on the first substrate 110 and on the second substrate 120 respectively and located between the first substrate 110 and the second substrate 120. Here, the moisture absorption layer 160 may have a continuous and closed annular structure that surrounds the environmental sensitive electronic device 130. In other exemplary embodiments of the disclosure, the moisture absorption layer 160 may have a closed structure or a non-closed structure that surrounds the environmental sensitive electronic device 130. For instance, the orthogonal projection of the moisture absorption layer 160 on the first substrate 110 and on the second substrate 120 may respectively be a U-shaped pattern, an L-shaped pattern, a dotted pattern, or any other pattern that may partially surround the environmental sensitive electronic device. According to the present exemplary embodiment, a shape of a cross-section of the moisture absorption layer 160 perpendicular to the first substrate 110 is a rectangular shape; said cross-section in other exemplary embodiments may be shaped as a circle or an ellipse, which should not be construed as a limitation in the disclosure.

In the present exemplary embodiment, the moisture absorption layer 160 may be located between adjacent first side wall barrier structure 142 and second side wall barrier structures 144 or between two adjacent second side wall barrier structures 144. The moisture absorption layer 160 may be alkaline-earth oxide that is able to absorb moisture and oxygen from the external environment, so as to improve the resistance of the environmental sensitive electronic device package 100A to oxygen and moisture.

With reference to FIG. 2A to FIG. 2G, in the present exemplary embodiment, the height of the second side wall barrier structure 144 may regularly or randomly vary along the paths P2 and P3; that is, the variation in the height of the second side wall barrier structure 144 may be in response to the actual height of surfaces of the internal components of the package. For instance, the height of the second side wall barrier structure 144 may be adjusted in response to the height of the circuit region 180 shown in FIG. 1A or the height of other unshown trace regions or IC bonding regions. Thereby, possible damages to the traces during the packaging process may be prevented, and moisture or oxygen can be effectively precluded from entering the package.

In an exemplary embodiment not shown in the drawings, the height of the first side wall barrier structure 142 may regularly or randomly vary along the path P1; that is, the variation in the height of the first side wall barrier structure 142 may be identical or similar to the variation in the height of the second side wall barrier structure 144 shown in FIG. 2A to FIG. 2G. That is, the variation in the height of the first side wall barrier structure 142 may also be in response to the actual heights of surfaces of the internal components of the package. For instance, the height of the first side wall barrier structure 142 may be adjusted in response to the height of the circuit region 180 shown in FIG. 1A or the height of other unshown trace regions or IC bonding regions. Thereby, possible damages to the traces during the packaging process may be prevented, and moisture or oxygen can be effectively precluded from entering the package.

Note that any different structural design or configuration that may prevent moisture infiltration and oxygen diffusion is still deemed an applicable technical scheme and falls within the scope of protection provided in the disclosure. Different exemplary embodiments detailing various designs of the environmental sensitive electronic device packages 100B to 100L are provided below. Here, identical or similar components in these packages share the identical or similar reference numbers and have the same or similar features, and therefore relevant explanations will not be provided hereinafter.

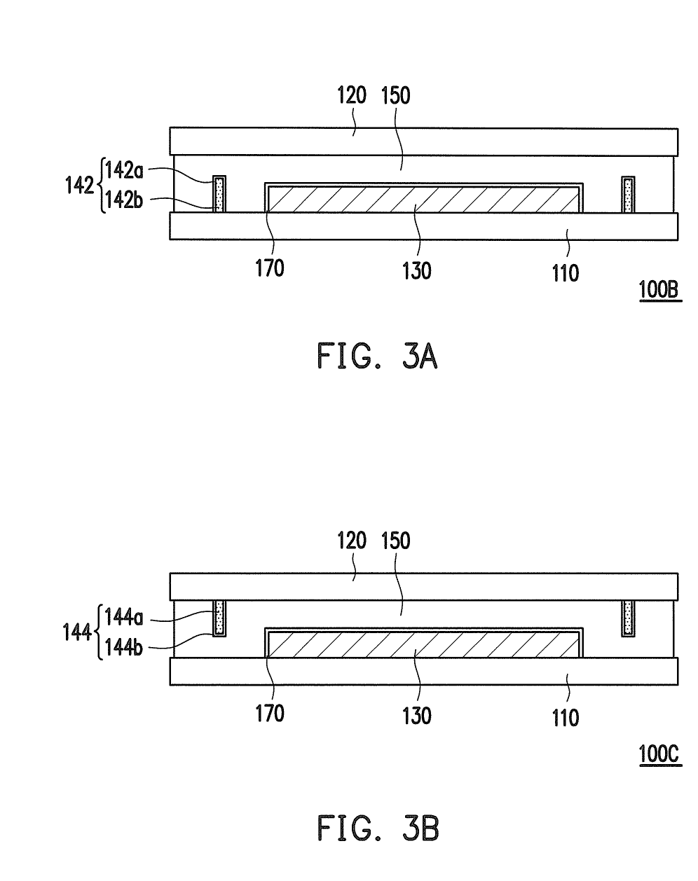

FIG. 3A and FIG. 3B are schematic cross-sectional diagrams respectively illustrating an environmental sensitive electronic device package according to another exemplary embodiment of the disclosure. For clear illustration, the circuit region 180 is not shown in FIG. 3A and FIG. 3B. The environmental sensitive electronic device package 100B shown in FIG. 3A is similar to the environmental sensitive electronic device package 100A shown in FIG. 1A, while the difference therebetween lies in that the environmental sensitive electronic device package 100B shown in FIG. 3A includes the first side wall barrier structure 142 located on the first substrate 110 but does not include the second side wall barrier structure 144 nor the moisture absorption layer 160. Such configuration can still prevent moisture infiltration and oxygen diffusion into the package, and thereby the lifetime of the environmental sensitive electronic device 130 may be effectively extended.

The environmental sensitive electronic device package 100C shown in FIG. 3B is similar to the environmental sensitive electronic device package 100A shown in FIG. 1A, while the difference therebetween lies in that the environmental sensitive electronic device package 100C shown in FIG. 3B includes the second side wall barrier structure 144 disposed on the second substrate 120 but does not include the first side wall barrier structure 142 nor the moisture absorption layer 160. Thereby, the same effects as those accomplished in view of the previous embodiment may also be achieved herein.

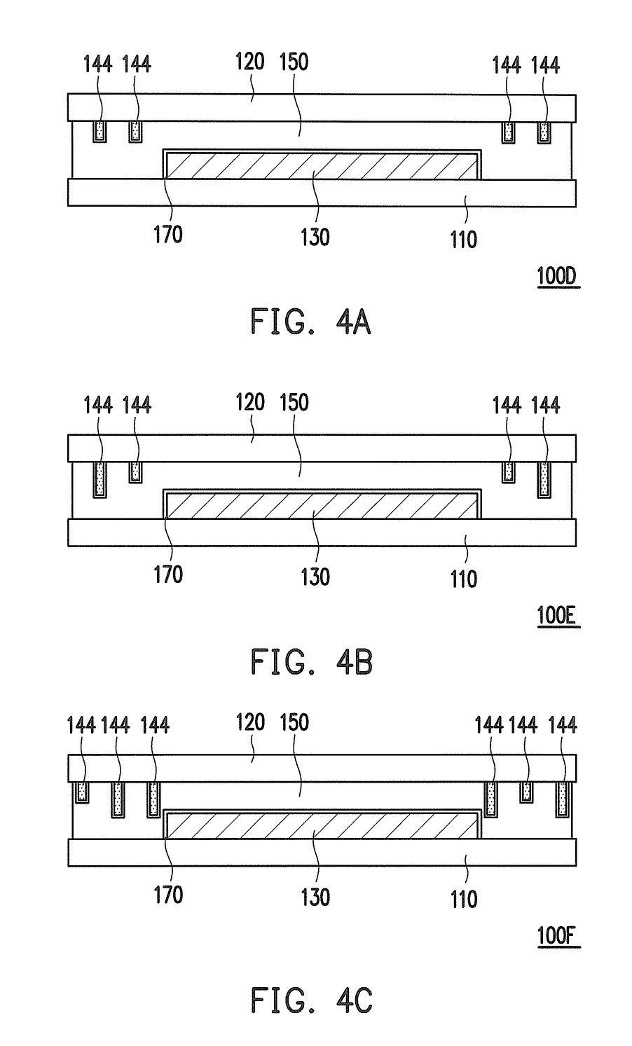

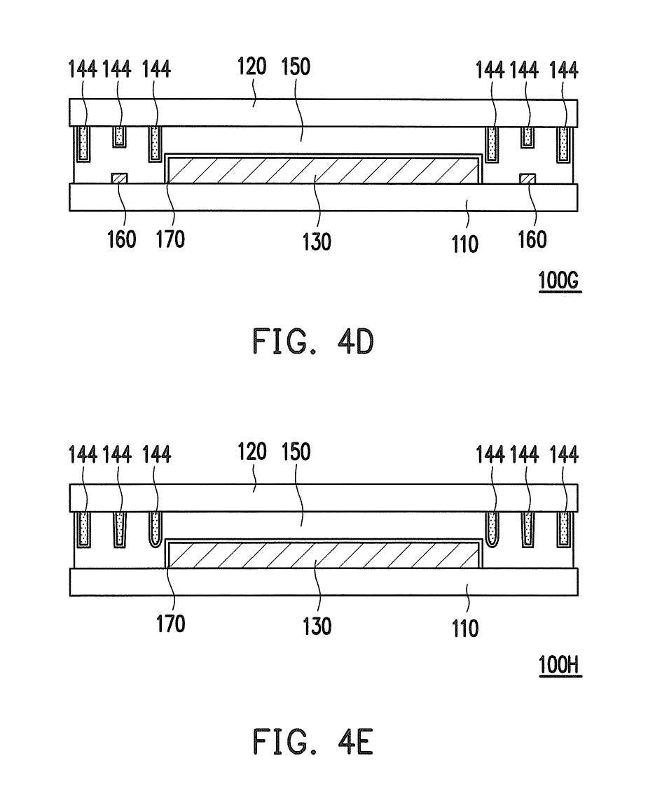

FIG. 4A to FIG. 4E are schematic cross-sectional diagrams respectively illustrating an environmental sensitive electronic device package according to another exemplary embodiment of the disclosure. For clear illustration, the circuit region 180 is not shown in FIG. 4A to FIG. 4E. The environmental sensitive electronic device package 100D shown in FIG. 4A is similar to the environmental sensitive electronic device package 100C shown in FIG. 3B, while the difference therebetween lies in that the number of the second side wall barrier structure 144 in the environmental sensitive electronic device package 100D shown in FIG. 4A is two or more. Here, the second side wall barrier structures 144 extending along the same path are at the peripheries of the environmental sensitive electronic device 130, and the second side wall barrier structures 144 at the two sides of the environmental sensitive electronic device 130 have the same height. In the present exemplary embodiment, the variation in the height of the second side wall barrier structure 144 may be in response to the actual height of surfaces of the internal components of the package. For instance, the height of the second side wall barrier structure 144 may be adjusted in response to the height of the circuit region 180 shown in FIG. 1A or the height of other unshown trace regions or IC bonding regions. Thereby, possible damages to the traces during the packaging process may be prevented, and moisture or oxygen can be effectively precluded from entering the package.

The environmental sensitive electronic device package 100E shown in FIG. 4B is similar to the environmental sensitive electronic device package 100D shown in FIG. 4A, while the difference therebetween lies in that the second side wall barrier structures 144 of the environmental sensitive electronic device package 100E extending along the same path are at the peripheries of the environmental sensitive electronic device 130, and the second side wall barrier structures 144 at the two sides of the environmental sensitive electronic device 130 do not have the same height. In the present exemplary embodiment, the variation in the height of the second side wall barrier structure 144 may be in response to the actual height of surfaces of the internal components of the package. For instance, the height of the second side wall barrier structure 144 may be adjusted in response to the height of the circuit region 180 shown in FIG. 1A or the height of other unshown trace regions or IC bonding regions. Thereby, possible damages to the traces during the packaging process may be prevented, and moisture or oxygen can be effectively precluded from entering the package.

The environmental sensitive electronic device package 100F shown in FIG. 4C is similar to the environmental sensitive electronic device package 100D shown in FIG. 4A, while the difference therebetween lies in that the number of the second side wall barrier structure 144 in the environmental sensitive electronic device package 100D shown in FIG. 4A is plural. Here, the second side wall barrier structures 144 extending along the same path are at the peripheries of the environmental sensitive electronic device 130. Some of the second side wall barrier structures 144 at the two sides of the environmental sensitive electronic device 130 may have the same height, while the others may have different heights. In the present exemplary embodiment, the variation in the height of the second side wall barrier structure 144 may be in response to the actual height of surfaces of the internal components of the package. For instance, the height of the second side wall barrier structure 144 may be adjusted in response to the height of the circuit region 180 shown in FIG. 1A or the height of other unshown trace regions or IC bonding regions. Thereby, possible damages to the traces during the packaging process may be prevented, and moisture or oxygen can be effectively precluded from entering the package.

The environmental sensitive electronic device package 100G shown in FIG. 4D is similar to the environmental sensitive electronic device package 100F shown in FIG. 4C, while the difference therebetween lies in that the first substrate 110 of the environmental sensitive electronic device package 100G shown in FIG. 4D has the moisture absorption layer 160 facing one of the second side wall barrier structures 144, for instance. In other words, the environmental sensitive electronic device package 100G not only achieves the same effects as those accomplished in view of the previous embodiments but also absorbs the moisture and oxygen from the surroundings by means of the moisture absorption layer 160.

The environmental sensitive electronic device package 100H shown in FIG. 4E is similar to the environmental sensitive electronic device package 100F shown in FIG. 4C, while the difference therebetween lies in that a shape of a cross-section of the second side wall barrier structures 144 perpendicular to the first substrate 110 may be a rectangular shape, a trapezoidal shape, or a bullet shape.

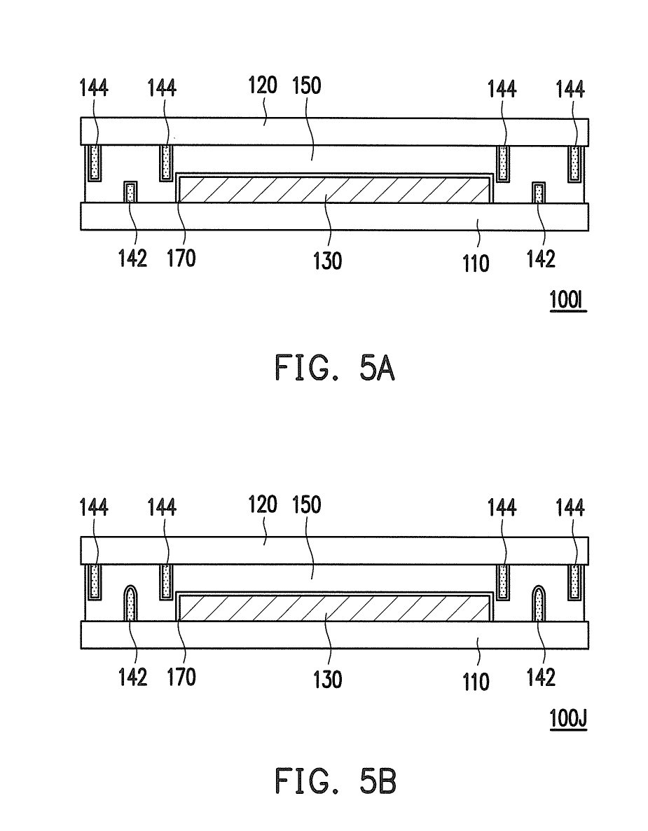

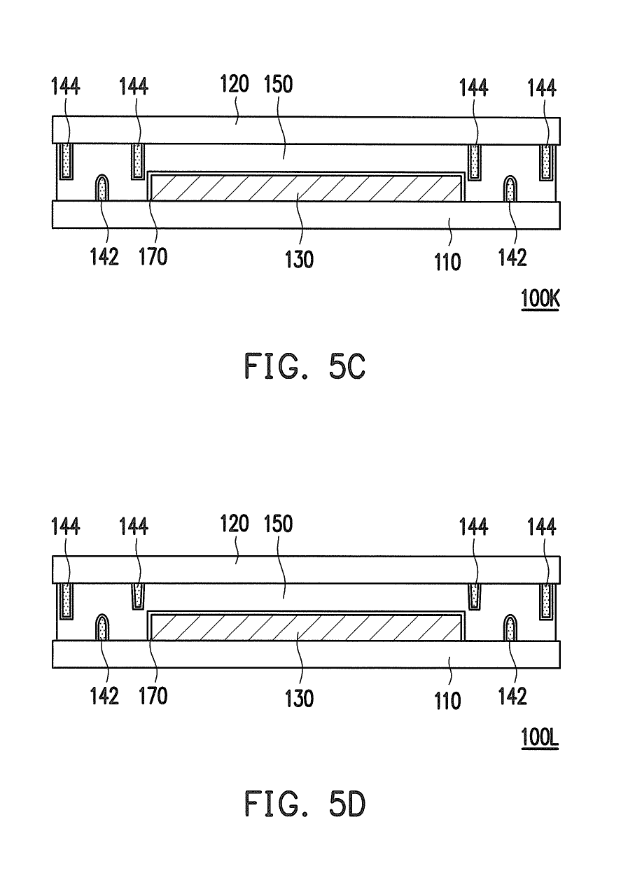

FIG. 5A to FIG. 5D are schematic cross-sectional diagrams respectively illustrating an environmental sensitive electronic device package according to another exemplary embodiment of the disclosure. For clear illustration, the circuit region 180 is not shown in FIG. 5A to FIG. 5D. The environmental sensitive electronic device package 100I shown in FIG. 5A is similar to the environmental sensitive electronic device package 100A shown in FIG. 1A, while the difference therebetween lies in that the environmental sensitive electronic device package 100I shown in FIG. 5A is not equipped with the moisture absorption layer 160. Here, the first side wall barrier structures 142 extending along the same path are at the peripheries of the environmental sensitive electronic device 130, and the first side wall barrier structures 142 at the two sides of the environmental sensitive electronic device 130 have the same height; the second side wall barrier structures 144 extending along the same path are at the peripheries of the environmental sensitive electronic device 130, and the second side wall barrier structures 144 at the two sides of the environmental sensitive electronic device 130 may also have the same height. The heights of the second side wall barrier structures 144 may be different from the height of the first side wall barrier structure 142.

The environmental sensitive electronic device package 100J shown in FIG. 5B is similar to the environmental sensitive electronic device package 100I shown in FIG. 5A, while the difference therebetween lies in that the shape of the cross-section of the first side wall barrier structures 142 of the environmental sensitive electronic device package 100J shown in FIG. 5B is the bullet shape, and the shape of a cross-section of the second side wall barrier structures 144 perpendicular to the first substrate 110 is the rectangular shape.

The environmental sensitive electronic device package 100K shown in FIG. 5C is similar to the package 100J shown in FIG. 5B, while the difference therebetween lies in that the heights of the second side wall barrier structures 144 of the environmental sensitive electronic device package 100K shown in FIG. 5C are different from the height of the first side wall barrier structure 142.

The environmental sensitive electronic device package 100L shown in FIG. 5D is similar to the environmental sensitive electronic device package 100K shown in FIG. 5C, while the difference therebetween lies in that the shape of the cross-section of the second side wall barrier structures 144 perpendicular to the first substrate 110 in the environmental sensitive electronic device package 100L may be a rectangular shape and a trapezoidal shape, respectively. The heights of the second side wall barrier structures 144 are different from the height of the first side wall barrier structure 142.

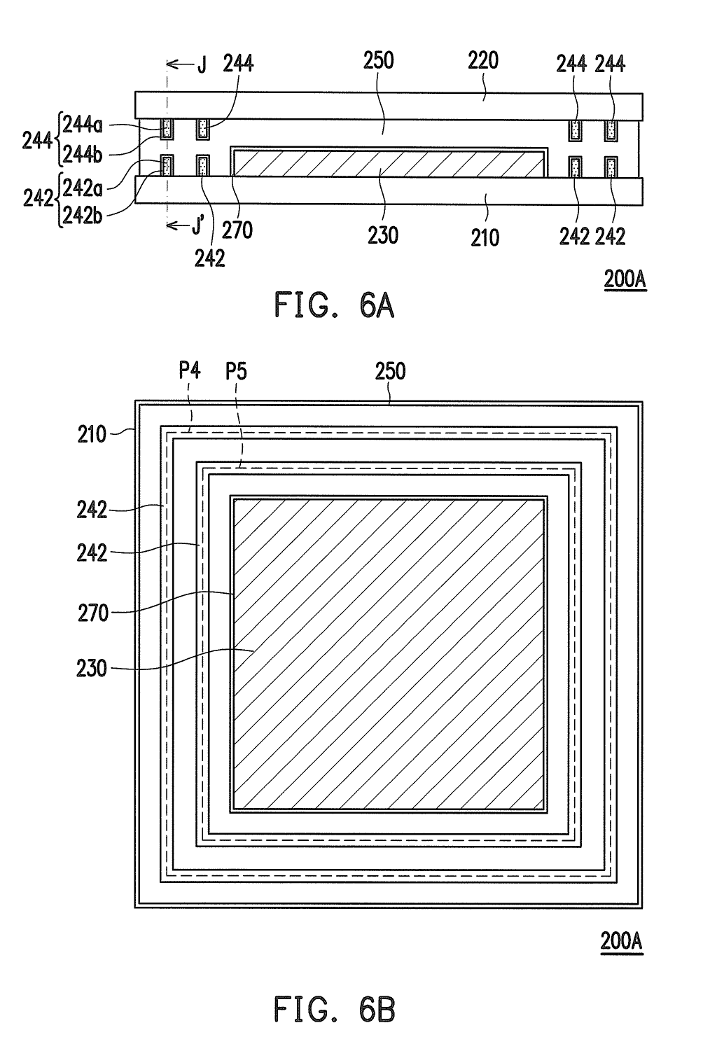

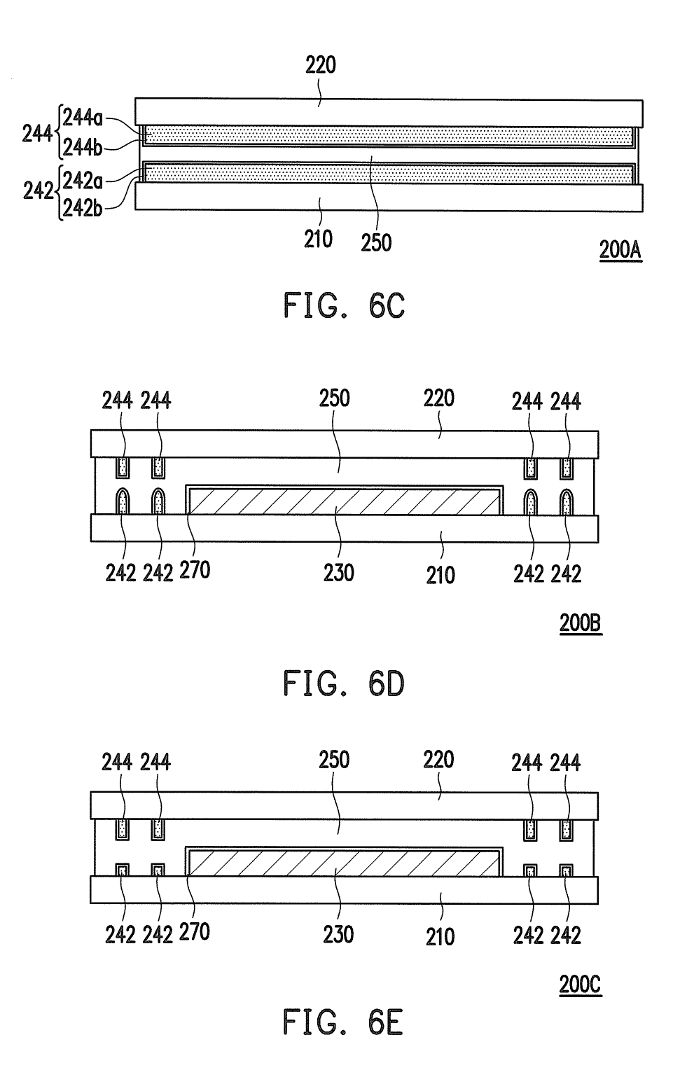

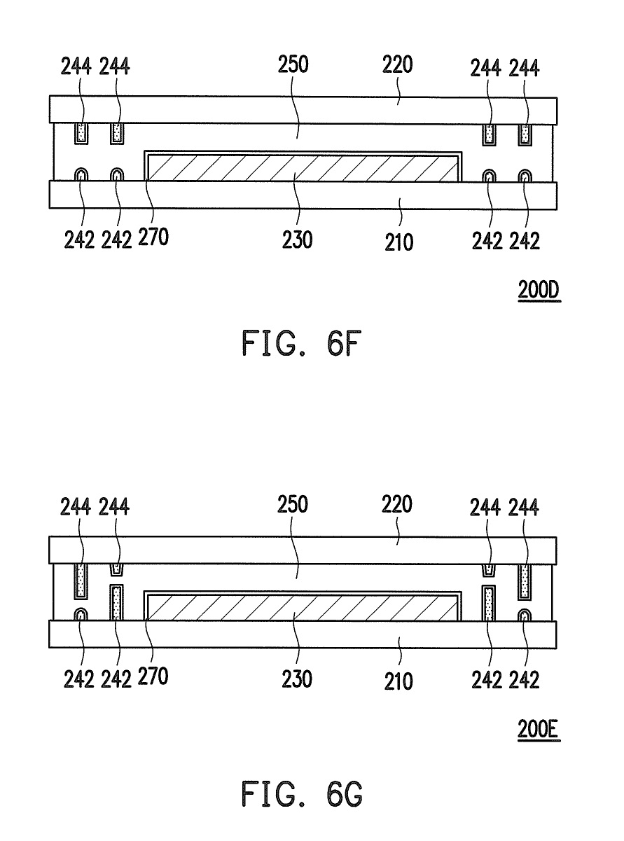

FIG. 6A is a schematic cross-sectional diagram illustrating an environmental sensitive electronic device package according to yet another exemplary embodiment of the disclosure. FIG. 6B is a top view illustrating the environmental sensitive electronic device package depicted in FIG. 6A. FIG. 6C is a schematic partial cross-sectional diagram illustrating the environmental sensitive electronic device package depicted in FIG. 6A along a sectional line J-J′. For clear illustration, the circuit region 180 is not shown in FIG. 6A to FIG. 6C. With reference to FIG. 6A to FIG. 6C, in the present exemplary embodiment of the disclosure, the environmental sensitive electronic device package 200A includes a first substrate 210, a second substrate 220, an environmental sensitive electronic device 230, first side wall barrier structures 242, second side wall barrier structures 244, and a filler layer 250. The second substrate 220 is disposed above the first substrate 210. The environmental sensitive electronic device 230 is disposed on the first substrate 210 and located between the first substrate 210 and the second substrate 220. The first side wall barrier structures 242 are disposed on the first substrate 210 and located between the first substrate 210 and the second substrate 220. Here, the first side wall barrier structures 242 surround the environmental sensitive electronic device 230. The first side wall barrier structures 242 respectively extend along paths P4 and P5, and the heights of the first side wall barrier structures 242 remain constant. Here, the heights of the first side wall barrier structures 242 on the paths P4 and P5 are exemplarily equivalent, which should however not be construed as a limitation in the disclosure.

The second side wall barrier structures 244 are disposed on the second substrate 220 and located between the first substrate 210 and the second substrate 220. Here, the second side wall barrier structures 244 surround the environmental sensitive electronic device 230. The second side wall barrier structures 244 respectively extend along paths (not shown in the drawings) similar to the paths P4 and P5, and the heights of the second side wall barrier structures 244 remain constant. Here, the heights of the second side wall barrier structures 244 on said paths (not shown) are exemplarily equivalent, which should however not be construed as a limitation in the disclosure. The filler layer 250 is located between the first substrate 210 and the second substrate 220 and covers the first side wall barrier structures 242, the second side wall barrier structures 244, and the environmental sensitive electronic device 230.

In the present exemplary embodiment, the first substrate 210 and the second substrate 220 are flexible substrates, for instance, and a material of the flexible substrates may be PET, PEN, PES, PMMA, PC, PI, or metal foil. The environmental sensitive electronic device package 200A may further include a functional film (not shown) exemplarily located on the first substrate 210 or on the second substrate 220. In general, the functional film may be a touch panel, and the touch panel may refer to a surface capacitive touch panel, a digital matrix touch panel (e.g., a projection capacitive touch panel), or an analog matrix touch panel, for instance. Certainly, the functional film may be a color filter or an EPD. In brief, the environmental sensitive electronic device package described in an exemplary embodiment of the disclosure is capable of performing the touch function.

The environmental sensitive electronic device 230 is, for instance, an active environmental sensitive electronic display device or a passive environmental sensitive electronic display device. The active environmental sensitive electronic display device is, for instance, an AM-OLED, an AM-EPD commonly known as electronic paper, an AM-LCD, or an AMBPLCD. The passive environmental sensitive electronic display device is, for instance, a PM-OLED or a STN-LCD. According to the present exemplary embodiment, the environmental sensitive electronic device 230 is covered by a passivation layer 270; in most cases, the passivation layer 270 may be an optical film or any other transparent polymer material film, which should not be construed as a limitation in the disclosure. The passivation layer 270 is capable of enhancing the brightness of the environmental sensitive electronic device 230 and blocking moisture and oxygen. Thereby, the lifetime of the environmental sensitive electronic device 230 may be extended.

As shown in FIG. 6A, the first side wall barrier structures 242 extend toward the second substrate 220, and the second side wall barrier structures 244 extend toward the first substrate 210. Here, the first side wall barrier structures 242 face the second side wall barrier structures 244, for instance. The cross-sections of the first side wall barrier structures 242 and the second side wall barrier structures 244 perpendicular to the first substrate 110 may have a rectangular shape, a trapezoidal shape, any other polygonal shape, a bullet shape, a circular shape, or an elliptic shape, which should not be construed as a limitation in the disclosure.

According to the present exemplary embodiment, each first side wall barrier structure 242 may further include a first barrier layer 242a and a first cover layer 242b. The first barrier layer 242a is located on the first substrate 210 and covered by the first cover layer 242b. A material of the first barrier layer 242a often includes an inorganic material or a mixture of inorganic and organic materials, and the first barrier layer 242a is formed on the first substrate 210 through etching, printing, photolithography, or the like, for instance. From another perspective, a material of the first cover layer 242b includes an inorganic material or a metal material. Here, the inorganic material is, for instance, silicon oxide, silicon nitride, silicon oxynitride, or aluminum oxide; the metal material is, for instance, molybdenum, titanium, aluminum, chromium, molybdenum/aluminum/molybdenum, or titanium/aluminum/titanium. The first cover layer 242b is formed on the first barrier layer 242a through wet coating, film evaporation, film sputtering, or the like, for instance. The first side wall barrier structures 242 and the first substrate 210 may be made of the same material or different materials, which should not be construed as a limitation in the disclosure.

According to the present exemplary embodiment, each second side wall barrier structure 244 may include a second barrier layer 244a and a second cover layer 244b. The second barrier layer 244a is located on the second substrate 220 and covered by the second cover layer 244b. A material of the second barrier layer 244a may include an inorganic material or a mixture of inorganic and organic materials, and the second barrier layer 244a is formed on the second substrate 220 through etching, printing, photolithography, or the like, for instance. From another perspective, a material of the second cover layer 244b includes an inorganic material or a metal material. Here, the inorganic material is, for instance, silicon oxide, silicon nitride, silicon oxynitride, or aluminum oxide; the metal material is, for instance, molybdenum, titanium, aluminum, chromium, molybdenum/aluminum/molybdenum, or titanium/aluminum/titanium. The second cover layer 244b is formed on the second barrier layer 244a through wet coating, film evaporation, film sputtering, or the like, for instance. The second side wall barrier structures 244 and the second substrate 220 may be made of the same material or different materials, which should not be construed as a limitation in the disclosure.

In other exemplary embodiments not shown in the drawings, the first and second side wall barrier structures 242 and 244 may be made of materials aside from said two types of materials; that is, the first side wall barrier structures 242 may be gas barrier structures having the first barrier layers 242a, and the second side wall barrier structures 244 may be gas barrier structures having the second barrier layers 244a.

As shown in FIG. 6B, in the present exemplary embodiment, the first side wall barrier structures 242 located on the first substrate 210 may have continuous and closed annular structures for blocking moisture and oxygen from the surroundings. Certainly, in the exemplary embodiments that are not shown, the second side wall barrier structures 244 located on the second substrate 220 may have continuous and closed annular structures similar to the first side wall barrier structures 242.

In another aspect, the filler layer 250 is formed by an adhesive that is cured by ultraviolet light or heat, for instance. The adhesive is, for instance, made of acrylic resin or epoxy resin. In the present exemplary embodiment, the filler layer 250 is a pressure-sensitive-type adhesive or a fill-type adhesive, for instance.

The first side wall barrier structures 242 of the environmental sensitive electronic device package 200A may face the second side wall barrier structures 244. Here, the heights and shapes of the cross-sections of the first side wall barrier structures 242 are the same as the heights and shapes of the cross-sections of the second side wall barrier structures 244 (facing the first side wall barrier structures 242), so as to effectively enhance the resistance of the environmental sensitive electronic device package 200A to moisture and oxygen.

Different exemplary embodiments detailing various designs of the environmental sensitive electronic device packages 200B to 200E are provided below. Here, identical or similar components in these packages share the identical or similar reference numbers and have the same or similar features, and therefore relevant explanations will not be provided hereinafter.

FIG. 6D to FIG. 6G are schematic cross-sectional diagrams illustrating an environmental sensitive electronic device package according to yet another exemplary embodiment of the disclosure. The environmental sensitive electronic device package 200B shown in FIG. 6D is similar to the environmental sensitive electronic device package 200A shown in FIG. 6A, while the difference therebetween lies in that the cross-sections of the first side wall barrier structures 242 perpendicular to the first substrate 210 in the environmental sensitive electronic device package 200B are shaped as bullets, and the cross-sections of the second side wall barrier structures 244 perpendicular to the first substrate 210 are shaped as rectangles. That is, in the present exemplary embodiment, the cross-sections of the first side wall barrier structures 242 and the cross-sections of the second side wall barrier structures 244 may have the same height but different shapes. Such configuration provided herein also achieves the same effects as those accomplished in view of the previous embodiments.

The environmental sensitive electronic device package 200C shown in FIG. 6E is similar to the package 200A shown in FIG. 6A, while the difference therebetween lies in that the heights of the cross-sections of the first side wall barrier structures 242 of the environmental sensitive electronic device package 200C are different from the heights of the cross-sections of the second side wall barrier structures 244. That is, in the present exemplary embodiment, the cross-sections of the first side wall barrier structures 242 and the cross-sections of the second side wall barrier structures 244 of the environmental sensitive electronic device package 200C may have different heights but the same shape. Such configuration provided herein also achieves the same effects as those accomplished in view of the previous embodiments.

The environmental sensitive electronic device package 200D shown in FIG. 6F is similar to the package 200B shown in FIG. 6D, while the difference therebetween lies in that the heights of the cross-sections of the first side wall barrier structures 242 of the environmental sensitive electronic device package 200D are different from the heights of the cross-sections of the second side wall barrier structures 244. That is, in the present exemplary embodiment, the cross-sections of the first side wall barrier structures 242 and the cross-sections of the second side wall barrier structures 244 of the environmental sensitive electronic device package 200D may have different heights and different shapes. Such configuration provided herein also achieves the same effects as those accomplished in view of the previous embodiments.

The environmental sensitive electronic device package 200E shown in FIG. 6G is similar to the environmental sensitive electronic device package 200A shown in FIG. 6A, while the difference therebetween lies in that the heights of the cross-sections of the first side wall barrier structures 242 of the environmental sensitive electronic device package 200E are different from the heights of the cross-sections of the second side wall barrier structures 244. Here, the cross-sections of the first side wall barrier structures 242 perpendicular to the first substrate 210 may be shaped as bullets and rectangles, and the cross-sections of the second side wall barrier structures 244 perpendicular to the first substrate 210 may be shaped as rectangles and trapezoids. The heights of the cross-sections of two adjacent first side wall barrier structures 242 are different from each other, and the heights of the cross-sections of two adjacent second side wall barrier structures 244 are different from each other. That is, in the present exemplary embodiment, the cross-sections of the first side wall barrier structures 242 and the cross-sections of the second side wall barrier structures 244 of the environmental sensitive electronic device package 200E have different heights and different shapes. Such configuration provided herein also achieves the same effects as those accomplished in view of the previous embodiments.

In the previous exemplary embodiments, the first and second side wall barrier structures 242 and 244 may have continuous and closed annular structures, which should however not be construed as a limitation in the disclosure. That is, each of the first and second side wall barrier structures may include a plurality of separated segments respectively surrounding the environmental sensitive electronic device along said extension path, and the heights of the separated segments remain constant.

In an exemplary embodiment of the disclosure, the side wall barrier structures are located between the first and second substrates of the environmental sensitive electronic device package. The side wall barrier structures extend along a path on the first substrate and/or on the second substrate and surround the environmental sensitive electronic device, and the heights of the side wall barrier structures may regularly or randomly vary along the path or remain constant on the path. In an exemplary embodiment of the disclosure, the heights of the side wall barrier structures may be adjusted in response to the actual heights of the surfaces of internal components in the environmental sensitive electronic device package, e.g., the heights of the trace regions, loop regions, or IC bonding regions. Thereby, possible damages to the traces during the packaging process may be prevented, moisture or oxygen can be effectively precluded from entering the package, and the lifetime of the environmental sensitive electronic device may then be extended.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An environmental sensitive electronic device package comprising:
a first substrate;
a second substrate disposed above the first substrate;
an environmental sensitive electronic device disposed on the first substrate and located between the first substrate and the second substrate;
at least one side wall barrier structure located between the first substrate and the second substrate, wherein the at least one side wall barrier structure surrounds the environmental sensitive electronic device and extends along a path, and a height of the at least one side wall barrier structure varies along the path; and
a filler layer located between the first substrate and the second substrate, the filler layer covering the at least one side wall barrier structure and the environmental sensitive electronic device.

2. The environmental sensitive electronic device package according to claim 1, further comprising a passivation layer covering the environmental sensitive electronic device.

3. The environmental sensitive electronic device package according to claim 1, wherein the at least one side wall barrier structure comprises a continuous and closed annular structure.

4. The environmental sensitive electronic device package according to claim 1, wherein the at least one side wall barrier structure comprises a plurality of separated segments, and a height of at least one of the separated segments varies along the path.

5. The environmental sensitive electronic device package according to claim 1, wherein a shape of a cross-section of the at least one side wall barrier structure perpendicular to the first substrate comprises a rectangular shape, a trapezoidal shape, a polygonal shape, a bullet shape, a circular shape, or an elliptic shape.

6. The environmental sensitive electronic device package according to claim 1, wherein the at least one side wall barrier structure comprises:
a barrier layer; and,
a cover layer covering the barrier layer.

7. The environmental sensitive electronic device package according to claim 1, wherein the at least one side wall barrier structure is located on the first substrate or on the second substrate.

8. The environmental sensitive electronic device package according to claim 1, wherein a number of the at least one side wall barrier structure is plural, and the side wall barrier structures comprise:
a first side wall barrier structure located on the first substrate and extended toward the second substrate; and
a second side wall barrier structure located on the second substrate and extended toward the first substrate, wherein the first side wall barrier structure and the second side wall barrier structure are alternately arranged between the first substrate and the second substrate.

9. The environmental sensitive electronic device package according to claim 8, wherein the first side wall barrier structure comprises:
a first barrier layer; and,
a first cover layer covering the first barrier layer.

10. The environmental sensitive electronic device package according to claim 8, wherein the second side wall barrier structure comprises:
a second barrier layer; and,
a second cover layer covering the second barrier layer.

11. The environmental sensitive electronic device package according to claim 1, further comprising a moisture absorption layer between the first substrate and the second substrate.

12. The environmental sensitive electronic device package according to claim 11, wherein the moisture absorption layer comprises a continuous and closed annular structure.

13. The environmental sensitive electronic device package according to claim 11, wherein a shape of a cross-section of the moisture absorption layer perpendicular to the first substrate or the second substrate comprises a rectangular shape, a circular shape, or an elliptic shape.

14. The environmental sensitive electronic device package according to claim 11, wherein the moisture absorption layer faces the at least one side wall barrier structure.

15. The environmental sensitive electronic device package according to claim 11, wherein the moisture absorption layer is located between two of the at least one side wall barrier structure adjacent to each other.

16. An environmental sensitive electronic device package comprising:
a first substrate;
a second substrate disposed above the first substrate;
an environmental sensitive electronic device disposed on the first substrate and located between the first substrate and the second substrate;
at least one first side wall barrier structure disposed on the first substrate and located between the first substrate and the second substrate, wherein the at least one first side wall barrier structure surrounds the environmental sensitive electronic device and extends along a path, and a height of the at least one first side wall barrier structure remains constant;
at least one second side wall barrier structure disposed on the second substrate and located between the first substrate and the second substrate, wherein the at least one second side wall barrier structure surrounds the environmental sensitive electronic device, the at least one second side wall extends along another path, and a height of the at least one second side wall barrier structure remains constant; and
a filler layer located between the first substrate and the second substrate, the filler layer covering the at least one first side wall barrier structure, the at least one second side wall barrier structure, and the environmental sensitive electronic device.

17. The environmental sensitive electronic device package according to claim 16, further comprising a passivation layer covering the environmental sensitive electronic device.

18. The environmental sensitive electronic device package according to claim 16, wherein the at least one first side wall barrier structure comprises a continuous and closed annular structure.

19. The environmental sensitive electronic device package according to claim 16, wherein the at least one first side wall barrier structure comprises a plurality of separated segments, and heights of the separated segments remain constant.

20. The environmental sensitive electronic device package according to claim 16, wherein the at least one second side wall barrier structure comprises a continuous and closed annular structure.

21. The environmental sensitive electronic device package according to claim 16, wherein the at least one second side wall barrier structure comprises a plurality of separated segments, and heights of the separated segments remain constant.

22. The environmental sensitive electronic device package according to claim 16, wherein a shape of a cross-section of the at least one first side wall barrier structure perpendicular to the first substrate comprises a rectangular shape, a trapezoidal shape, a polygonal shape, a bullet shape, a circular shape, or an elliptic shape.

23. The environmental sensitive electronic device package according to claim 16, wherein a shape of a cross-section of the at least one second side wall barrier structure perpendicular to the first substrate comprises a rectangular shape, a trapezoidal shape, a polygonal shape, a bullet shape, a circular shape, or an elliptic shape.

24. The environmental sensitive electronic device package according to claim 16, wherein the at least one first side wall structure comprises:
a first barrier layer; and,
a first cover layer covering the first barrier layer.

25. The environmental sensitive electronic device package according to claim 16, wherein the at least one second side wall barrier structure comprises:
a second barrier layer; and,
a second cover layer covering the second barrier layer.

26. The environmental sensitive electronic device package according to claim 16, wherein the at least one first side wall barrier structure extends toward the second substrate, the at least one second side wall barrier structure extends toward the first substrate, and the at least one first side wall barrier structure faces the at least one second side wall barrier structure.
